(19) United States
(12) Patent Application Publication
(10) Pub. No.: US 2025/0334626 A1
(43) Pub. Date: Oct. 30, 2025

(54) METHODS AND APPARATUS TO DETERMINE ELECTRICAL PROPERTIES OF COMPONENTS

(71) Applicant: Texas Instruments Incorporated, Dallas, TX (US)

(72) Inventors: Ritesh Waykole, Tucson, AZ (US); Vadim Ivanov, Dallas, TX (US); Sai Bharadwaj Medapuram, Tucson, AZ (US); Maseehullah Syed, Tucson, AZ (US); Nidhish Kamat, Tucson, AZ (US); Biraja Dash, Tucson, AZ (US)

(21) Appl. No.: 18/646,440

(22) Filed: Apr. 25, 2024

(51) Int. Cl. G01R 31/28; G01R 19/165

(52) U.S. Cl. CPC G01R 31/2858; G01R 19/16519; G01R 31/2889

(57) ABSTRACT

Methods, apparatus, systems, and articles of manufacture are described to determine electrical properties of external components. An example system includes a controller to output an indication to a first input/output pin based on a comparison of a temperature to a threshold; a first pull-up resistor having a first terminal coupled to the first input/output pin and a second terminal coupled to a voltage supply; and a resistor decoder to output a voltage having a voltage based on a resistance of the first pull-up resistor, wherein the controller is to determine the threshold based on the voltage.

### TECHNICAL FIELD

This description relates generally to circuitry, and, more particularly, to methods and apparatus to determine electrical properties of components.

### BACKGROUND

Sensors gather information related to a physical environment. Sensors may include temperature sensors, image sensors, current/voltage sensors, or any other device that gathers information related to a physical environment. For example, temperature sensors determine the temperature of a physical environment. Also, a temperature sensor can process the determined temperature to trigger an alert after the temperature crosses a threshold. In some examples, the temperature sensor can output a signal to a device in response to the triggered alert.

### SUMMARY

For correcting determining electrical properties of components, an example integrated circuit includes an input/output pin; a common terminal; a capacitor having a first terminal and a second terminal, the first terminal coupled to the input/output pin and a second terminal coupled to a differential amplifier; the differential amplifier having a first input terminal, a second input terminal, and an output terminal, the first input terminal coupled to the second terminal of the capacitor, the second input terminal coupled to a voltage source; a first switch having a first terminal and a second terminal, the first terminal of the first switch coupled to the first input terminal of the differential amplifier and the second terminal of the capacitor, the second terminal of the first switch coupled to the voltage source and the common terminal; a resistor having a first terminal and a second terminal, the second terminal coupled to the common terminal; and a second switch having a first terminal and a second terminal, the first terminal coupled to the output terminal of the differential amplifier, the second terminal coupled to the input/output pin, the first terminal of the capacitor, and the first terminal of the resistor. Other examples are described.

For correcting determining electrical properties of components, an example system includes a first pull-up resistor; a microcontroller having an input terminal coupled to the first pull-up resistor; and an integrated circuit including: a first input/output pin coupled to the first pull-up resistor and the input terminal of the microcontroller; a capacitor having a first terminal and a second terminal, the first terminal coupled to the first input/output pin and a second terminal coupled to a differential amplifier; the differential amplifier having a first input terminal, a second input terminal, and an output terminal, the first input terminal coupled to the second terminal of the capacitor, the second input terminal coupled to a voltage source; a first switch having a first terminal and a second terminal, the first terminal of the first switch coupled to the first input terminal of the differential amplifier and the second terminal of the capacitor, the second terminal of the first switch coupled to the voltage source and a common terminal; a resistor having a first terminal and a second terminal, the second terminal coupled to the common terminal; and a second switch having a first terminal and a second terminal, the first terminal coupled to the output terminal of the differential amplifier, the second terminal coupled to the first input/output pin, the first terminal of the capacitor, and the first terminal of the resistor. Other examples are described.

For correcting determining electrical properties of components, an example system includes a controller to output an indication to a first input/output pin based on a comparison of a temperature to a threshold; a first pull-up resistor having a first terminal coupled to the first input/output pin and a second terminal coupled to a voltage supply; and a resistor decoder to output a voltage having a voltage based on a resistance of the first pull-up resistor, wherein the controller is to determine the threshold based on the voltage. Other examples are described.

### BRIEF DESCRIPTION OF THE DRAWINGS

FIG. 1 is an example block diagram of a system including a sensor with a decoder to determine electrical properties of components.

FIG. 2 is an example circuit implementation of the decoder of FIG. 1 to determine an electrical property of a component.

FIG. 3 is an alternative example circuit implementation of the decoder of FIG. 1 to determine two electrical properties of two components.

FIG. 4 is a flowchart representative of example machine readable instructions or example operations that may be executed, instantiated, or performed by example programmable circuitry to implement the controller of FIG. 1.

FIG. 5 illustrates an example first phase of operation of switches in the decoder of FIG. 3.

FIG. 6 illustrates an example second phase of operation of switches in the decoder of FIG. 3.

FIG. 7 is an example system diagram including circuitry that implements the decoder of FIGS. 1-3, 5, and 6.

FIG. 8 is an example system implementation of the sensor of FIG. 1.

FIG. 9 illustrates example pull-up resistance values and corresponding temperature limits that could be used by pull-up resistors of FIGS. 1, 3, and 5-7.

FIG. 10 is a block diagram of an example processing platform including programmable circuitry structured to execute, instantiate, or perform the example machine readable instructions or perform the example operations of FIG. 4 to implement the controller of FIG. 1.

The same reference numbers or other reference designators are used in the drawings to designate the same or similar (functionally or structurally) features.

### DETAILED DESCRIPTION

The drawings are not necessarily to scale. Although the drawings show regions with clean lines and boundaries, some or all of these lines or boundaries may be idealized. In reality, the boundaries or lines may be unobservable, blended or irregular.

Sensors obtain samples to determine information related to an environment. Some sensors may process the obtained information to output alerts if the information corresponds to undesirable environmental conditions. For example, a temperature sensor may determine a temperature and output one or more alerts if the temperature goes above or below one or more thresholds. The temperature sensor includes one or more pins that are dedicated to the alerts.

The alert pin(s) on a sensor are coupled to a device (e.g., a processing unit, such as a central processing unit (CPU), a microcontroller unit (MCU), a graphics processing unit (GPU), etc.) to alert the device if the determined information crosses one or more thresholds. For example, if the sensor outputs an active logic low voltage to the device via a first alert pin, the device determines that the alert has been triggered. In such a design, the node between the alert pin and the device is coupled to a supply voltage via a pull-up resistor to pull-up the voltage of the node to the supply voltage. The pull-up resistor ensures that the voltage at the node is pulled to a high logic level in the absence of an input signal from the alert pin.

During manufacturing or implementation of a sensor into a system, the user or manufacturer can select the resistance(s) of the pull-up resistor(s) to set the alert threshold(s) for desired temperature limits. However, in order for the sensor to set the alert threshold(s), the sensor needs to know the resistance value of the pull-up resistor(s). Examples described herein provide decoder circuitry for determining the resistance of the pull-up resistor.

Although the resistance can be determined by forcing current to the resistor and measuring the voltage drop across the resistor, doing so may cause other issues in the system. For example, a low voltage at the node between the alert pin of the sensor and the other device triggers an alert to the other device. Thus, if the process of determining the resistance of the pull-up resistor lowers the node voltage too low, that low node voltage may trigger an alert to the other device. Another possible issue is that the supply voltage that the pull-up resistor is coupled to may be different from the supply voltage of the sensor, thereby leading to miscalculations. Examples described herein utilize decoder circuitry including a sampling capacitor and a feedback path to generate a current and voltage that corresponds to a resistance of the pull-up resistor coupled to the alert pin of a sensor. Although examples described herein are described in conjunction with determining resistance of a pull-up resistor via a temperature sensor. Examples described herein can be used to determine any electrical property using a decoder that may be implemented in any device or sensor.

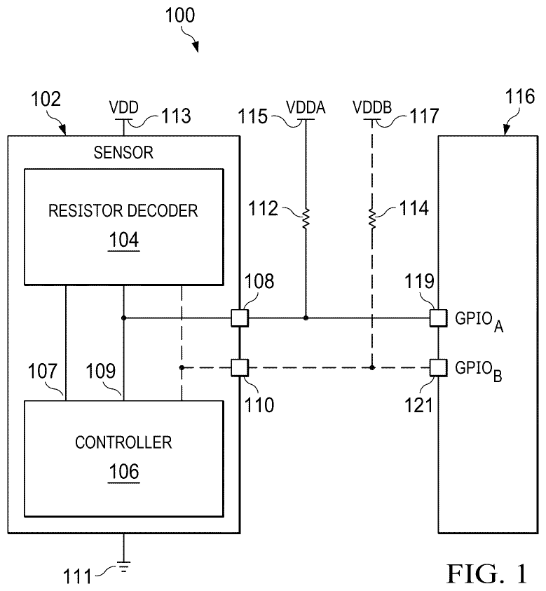

FIG. 1 illustrates example system 100 with an example sensor 102 including an example resistor decoder 104 to determine the resistances of pull-up resistors. The sensor 102 further includes an example controller 106 and example input/output pins 108, 110. The system 100 further includes example resistors 112, 114 and an example device 116.

The sensor 102 of FIG. 1 is a temperature sensor. However, the sensor 102 can be any type of sensor or a different type of device. The sensor 102 has a first alert pin 108 and an optional second alert pin 110. However, the sensor 102 can include any number of alert pins. The first alert pin 108 is an input/output pin that is coupled to the resistor decoder 104, the controller 106, the second terminal of the resistor 112 and the first general-purpose input output (GPIO) pin of the device 116. The second alert pin 110 is an input/output pin that is coupled to the resistor decoder 104, the controller 106, the second terminal of the resistor 114 and a second GPIO pin of the device 116. The sensor 102 is structured to be coupled to an example supply terminal (VDD) 113 (also known as a supply voltage terminal, a reference terminal, a reference voltage terminal, etc.) and an example common terminal (e.g., ground) 111. The sensor 102 senses a temperature and converts the temperature into a digital value that can be used to determine the temperature. Also, the sensor 102 can output a signal to the device 116 via the alert (e.g., a warning alert) pin 108 if the temperature does not cross a first threshold. Also, the sensor 102 can output a second signal to the device 116 via the alert (e.g., a critical alert) pin 110 if the temperature does not cross a second threshold. However, as described above, there may be other alert pins that correspond to other thresholds.

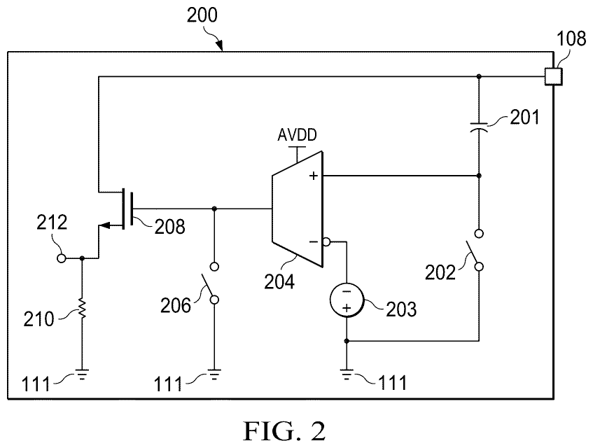

The resistor decoder 104 of FIG. 1 is circuitry to determine the resistance of pull-up resistors (e.g., the resistors 112, 114) that are coupled to the pin(s) 108, 110. In some examples, the resistor decoder 104 may be any other type of decoder (e.g., an inductance decoder, a capacitance decoder, etc.). The resistor decoder 104 includes at least two terminals. In the example of FIG. 1, the first terminal of the resistor decoder 104 is coupled to the alert pin 108 and the controller 106. The second terminal of the resistor decoder 104 is coupled to the alert pin 110 and the controller 106. The third terminal of the resistor decoder 104 is coupled to the controller 106. As further described below, the resistor decoder 104 includes circuitry to determine the resistance of the resistor 112. In some examples, the resistor decoder 104 may also determine the resistance of the resistor 114. For example, the resistor decoder 104 uses a capacitor to store and hold a voltage at the pin(s) 108, 110 during a first phase of operation. During a second phase of operation, the resistor decoder 104 discharges the voltage stored in the capacitor to control the amount of current that is passed through a resistor to generate an output voltage that corresponds to a resistance of one of the resistor(s) 112, 114. The resistor decoder 104 outputs the voltage corresponding to the resistance of the resistor(s) 112, 114 to the controller 106. The resistor decoder 104 of FIG. 1 is further described below in conjunction with FIG. 2.

The controller 106 of FIG. 1 processes the output voltage from the resistor decoder 104 to determine the resistance of the resistor(s) 112, 114. The controller 106 includes at least two terminals. The first terminal 107 of the controller 106 is coupled to the resistor decoder 104. The second terminal 109 of the controller 106 is coupled to the first alert pin 108 and the resistor decoder 104 and is structured to be coupled to the resistor 112 and a GPIOA pin 119 of the device 116. The third optional terminal of the controller 106 is coupled to the second alert pin 110 and the resistor decoder 104 and is structured to be coupled to the resistor 114 and a GPIOB pin 121 of the device 116. In some examples, the controller 106 may have additional terminals for additional alert pins. The controller 106 converts the analog voltage value into a digital value and determines the resistance of the resistor(s) 112, 114 based on the digital value. In some examples, the controller 106 includes an analog-to-digital converter to convert the analog voltage signal into a digital value. After the controller 106 determines the resistance of the resistor 112, 114, the controller 106 stores the digital value corresponding to the resistance in memory (e.g., local memory, volatile memory, non-volatile memory, a buffer, a register, storage, etc.). In some examples, the controller 106 can set the alert threshold(s) based on the resistance of the resistor(s) 112, 114. In this manner, a user or manufacturer can select the alert threshold(s) for the sensor 102 based on the resistance(s) of the resistor(s) that they select for implementation of the resistor(s) 112, 114. The controller 106 can compare a sensed temperature or other characteristic to the threshold and output one or more indications (e.g., output signals) based on the comparison. The controller 106 can store a lookup table that correlates resistance values of the external pull-up resistor to threshold temperature values for determining when an indication should will be generated. Also, the controller 106 controls one or more switches in the resistor decoder 104 to implement the first and second phases of a resistor decoding protocol to determine the resistance of the resistors 112, 114. In some examples, the controller 106 includes one or more state machines. For example, the controller 106 can include a first state machine to control the switches of the resistor decoder 104 and a second state machine to determine the resistance of one or more of the resistors 112, 114 based on the output voltage generated by the resistor decoder 104 (e.g., after being converted into a digital value).

The resistor 112 of FIG. 1 includes a first terminal and a second terminal. The first terminal of the resistor 112 is coupled to an example supply terminal (e.g., VDDA) 115. The supply terminal 115 may be the same or different than the supply terminals VDD 113, VDDB 117. The second terminal of the resistor 112 is structured to be coupled to the alert pin 108 of the sensor 102 and the GPIOA pin 119 of the device 116. The resistor 112 is a pull-up resistor that has a resistance. The resistor 112 causes the voltage at the node between the first alert pin 108 and the GPIOA pin 119 to be pulled to the supply voltage if the sensor 102 is not outputting a low voltage to indicate an alert. As described above, a user or manufacturer can select the resistor 112 with a particular resistance to set the threshold at which the sensor 102 outputs one or more alerts. For example, a user can select a resistance of 2,000 Ohms if the user wants an alert to be triggered if the temperature determined by the sensor 102 is above 77 degrees Celsius, a resistance of 7,500 Ohms if the user wants an alert to be triggered if the temperature determined by the sensor 102 is above 79 degrees Celsius, etc.

The resistor 114 of FIG. 1 includes a first terminal and a second terminal. The first terminal of the resistor 114 is coupled to an example supply terminal (e.g., VDDB) 117. The supply terminal 117 may be the same or different than the supply terminals VDD 113, VDDA 115. The second terminal of the resistor 114 is structured to be coupled to the alert pin 110 of the sensor 102 and the GPIOB pin 121 of the device 116. The resistor 114 is a pull-up resistor that has a resistance. The resistor 114 causes the voltage at the node between the second alert pin 110 and the GPIOB pin 121 to be pulled to the supply voltage if the sensor 102 is not outputting a low voltage to indicate an alert. As described above, a user or manufacturer can select the resistor 114 with a particular resistance to set the threshold at which the sensor 102 outputs one or more alerts. For example, a user can select a resistance of 2,000 Ohms if the user wants an alert to be triggered if the temperature determined by the sensor 102 is above 77 degrees Celsius, a resistance of 7,500 Ohms if the user wants an alert to be triggered if the temperature determined by the sensor 102 is above 79 degrees Celsius, etc.

The device 116 of FIG. 1 is a device that utilizes the information from the sensor 102. The device 116 includes an example first terminal (e.g., corresponding to the GPIOA pin) 119 and an optional second terminal (e.g., corresponding to the GPIOB pin) 121. The first terminal of the device 116 is structured to be coupled to the second terminal of the resistor 112 and the sensor 102 via the first alert pin 108. The second terminal of the device 116 is structured to be coupled to the second terminal of the resistor 114 and the second alert pin 110. The device 116 may be any type of processing device or unit that, if the voltage at the GPIOA pin 119 or the GPIOB pin 121 drops to a low voltage, determines that the temperature measured by the sensor 102 does not cross one or more thresholds. In some examples, the device 116 performs one or more actions based on the low voltage at the GPIO pin(s).

FIG. 2 is a block diagram of an example implementation 200 of the resistor decoder 104 of FIG. 1. The example circuitry 200 includes an example capacitor 201, an example switch 202, an example voltage source 203, an example amplifier 204 an example switch 206, an example transistor 208, and an example resistor 210. The implementation 200 of FIG. 2 determines the resistance of the resistor 112 of FIG. 1 which is coupled to the alert pin 108.

The capacitor 201 of FIG. 2 includes a first terminal and a second terminal. The first terminal of the capacitor 201 is coupled to the alert pin 108 and the first current terminal of the transistor 208. The second terminal of the capacitor 201 is coupled to the first input terminal of the amplifier 204 and the first terminal of the switch 202. The capacitor 201, if the switch 202 is closed (e.g., creating a short circuit) during a first phase, stores a voltage corresponding to the voltage at the alert pin 108 which corresponds to the voltage at the second terminal of the resistor 112. If the switch 202 is open (e.g., creating an open circuit) during a second phase, the capacitor 201 holds the sampled voltage at the second (e.g., bottom) plate of the capacitor 201 because the second plate of the capacitor 201 is coupled to the high impedance state at the first input terminal of the amplifier.

The switch 202 of FIG. 2 is a switch that can be opened (e.g., disabled or operate as an open circuit) or closed (e.g., enabled or operate as a closed switch) based on a signal from the controller 106 of FIG. 1. The switch 202 includes a first terminal and a second terminal. The first terminal of the switch 202 is coupled to the first input terminal of the amplifier 204 and the second terminal of the capacitor 201. The second terminal of the switch 202 is coupled to a common terminal (e.g., ground) 111 and a second terminal of the voltage source 203. In some examples, the switch 202 includes a third terminal coupled to the controller 106 of FIG. 1 to control whether the switch 202 is enabled/disabled. The controller 106 of FIG. 1 closes the switch 202 during the first phase and opens the switch 202 during the second phase. In some examples, the switch 202 is implemented by a transistor (e.g., a field effect transistor (FET)).

The voltage supply 203 of FIG. 2 generates a bias voltage. The voltage supply 203 includes a first terminal and a second terminal. The first terminal of the voltage supply 203 is coupled to the second input terminal of the amplifier 204. The second terminal of the voltage supply 203 is coupled to the common terminal 111 and the second terminal of the switch 202. The voltage supply 203 generates a voltage small enough to keep the voltage at the alert pin 108 from dropping below a threshold, but large enough so that the output of the amplifier 204 is above a threshold voltage large enough to control the transistor 208. For example, the reference voltage may generate a voltage of −200 millivoltage (mV) at the second input terminal of the amplifier 204.

The amplifier 204 of FIG. 2 is a differential amplifier that amplifies a difference between the voltage at the first input terminal and the voltage at the second input terminal. The amplifier 204 includes a first input terminal, a second input terminal, and an output terminal. The first input terminal (e.g., a non-inverting input) of the amplifier 204 is coupled to the second terminal of the capacitor 201 and the first terminal of the switch 202. The second input terminal (e.g., an inverting input) of the amplifier 204 is coupled to the first terminal of the voltage supply. In the example of FIG. 2, the second input terminal is inverted so that the opposite of the input voltage is applied to the inverting input of the amplifier 204. For example, if the voltage at the first input terminal is X Volts and the voltage at the second input terminal is Y Volts, the amplifier 204 will output voltage is A(X−(−Y)), where A is the gain of the amplifier 204. The amplifier 204 outputs the amplified difference between the voltages at the two input terminals at the output terminal of the amplifier 204.

The switch 206 of FIG. 2 is a switch that can be opened (e.g., disabled or operate as an open circuit) or closed (e.g., enabled or operate as a closed switch) based on a signal from the controller 106 of FIG. 1. The switch 206 includes a first terminal and a second terminal. The first terminal of the switch 206 is coupled to the output terminal of the amplifier 204 and the control terminal of the transistor 208. The second terminal of the switch 206 is coupled to a common terminal (e.g., ground) 111. In some examples, the switch 206 includes a third terminal coupled to the controller 106 of FIG. 1 to control whether the switch 206 is enabled/disabled. The controller 106 of FIG. 1 closes the switch 206 during the first phase and opens the switch 206 during the second phase. In some examples, the switch 206 is implemented by a transistor (e.g., a field effect transistor (FET)).

The transistor 208 of FIG. 2 can cause current to flow from a first current terminal of the transistor 208 to a second current terminal of the transistor 208. The transistor 208 includes a first current terminal (e.g., a drain terminal), a second current terminal (e.g., a source terminal), and a control terminal (e.g., a gate terminal). The first current terminal of the transistor 208 is coupled to the first terminal of the capacitor 201 and the alert pin 108. The second current terminal of the transistor 208 is coupled to the first terminal of the resistor 210 and the controller 106 of FIG. 1 (e.g., via an example output terminal 212). The transistor 208 of FIG. 2 is an N-channel metal oxide field effect transistor (NMOS transistor or N-channel MOSFET). However, the transistor 208 can be any type of transistor. The voltage at the control terminal of the transistor 208 determines how much current will flow from the first current terminal to the second current terminal. For example, if the voltage at the control terminal of the transistor 208 is grounded (e.g., 0V), the transistor 208 acts as an open switch to block current at the first current terminal from flowing to the second current terminal. If the voltage at the control terminal of the of the transistor 208 is above 0V, the transistor 208 causes current to flow from the first current terminal to the second current terminal, the amount of current being based on the voltage at the control terminal of the transistor 208.

The resistor 210 of FIG. 2 is an output resistor. The resistor 210 includes a first terminal and a second terminal. The first terminal of the resistor 210 is coupled to the second current terminal of the transistor 208 and the controller 106 of FIG. 1 (via the output terminal 212). The second terminal of the resistor 210 is coupled to the common terminal 111. The output resistor 210 generates a path to ground for the current from the second current terminal of the transistor 208 to flow toward, thereby generating a voltage at the first terminal of the resistor 210. The voltage at the first terminal of the resistor 210 corresponds to the resistance of the resistor 112 of FIG. 1. The voltage is transmitted to the controller 106 of FIG. 1 to determine the resistance of the resistor 112.

In operation, during the first phase, the controller 106 closes the switches 202, 206. Thus, the voltage from the supply terminal VDDA 115 across the resistor 112 is stored in the capacitor 201 and the output of the amplifier 204 is grounded. Accordingly, the transistor 208 is disabled to prevent current from flowing from the first current terminal of the transistor 208 to the second current terminal of the transistor 208. After a duration of time (e.g., after the capacitor 201 has charged to the VDDA supply voltage, the controller 106 opens the switches 202, 206. Because the second plate of the capacitor 201 is coupled to the high impedance of the amplifier 204, the capacitor 201 holds the stored voltage. During the second phase, the amplifier 204 controls the transistor 208 to regulate the input terminals of the amplifier 204 to correspond to the same voltage. Accordingly, because the voltage at the second input terminal corresponds to the offset voltage generated by the voltage source 203 (e.g., −200 mV), the amplifier 204 controls the transistor 208 to regulate the voltage at the first input voltage to −200 mV. Thus, if the voltage at the second terminal is −200 mV and the capacitor stores a VDDA voltage, the voltage at the first terminal of the capacitor is VDDA-200 mV. Accordingly, the current through the resistor 112 and into the first current terminal of the transistor 208 is 200 mV/R112 (e.g., (VDDA-(VDDA-200 mV))/R112), where R112 is the resistance of the resistor 112. Also, during the second phase the amplifier 204 outputs a voltage to the control terminal of the transistor 208 and transistor 208 allows the current (e.g., 200 mV/R112) at the first terminal to flow to the second terminal. Thus, the current across the resistor 210 generates a voltage at the first terminal of the resistor 210 (e.g., (200 mV)/R112)*Rout) that is input into an ADC of the controller 106. Because the Rout resistance is known, the controller can solve for resistance of the resistor 112 based on the voltage at the first terminal of the resistor 210.

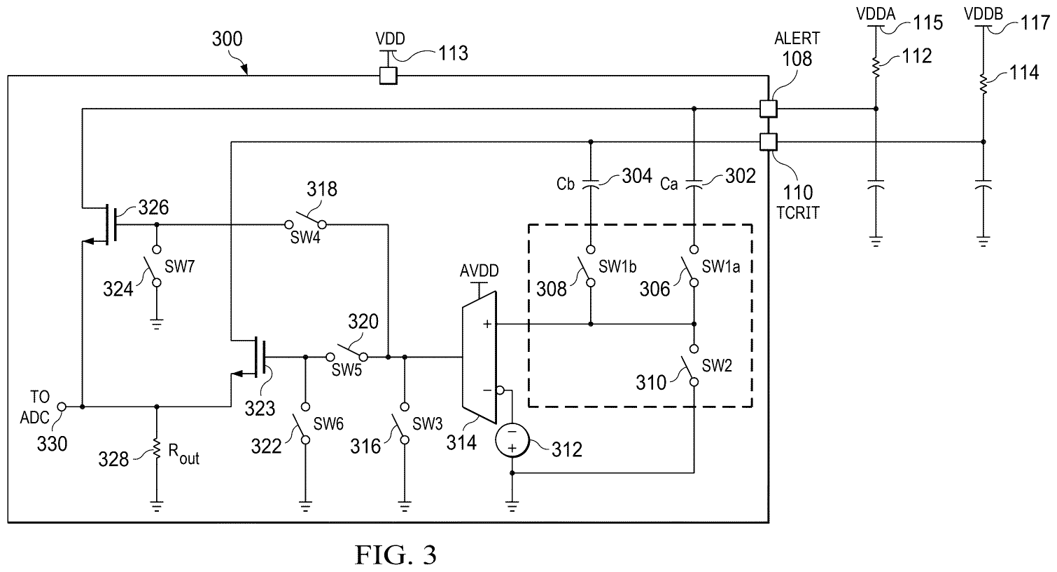

FIG. 3 illustrates example circuitry 300 for implementing of the resistor decoder 104 of FIG. 1 with two alerts for the two alert pins 108, 110. The example circuitry 300 includes example capacitors 302, 304, example switches 306, 308, 310, 316, 318, 320, 322, 324, an example voltage generator 312, an example amplifier 314, example transistors 323, 326, and an example resistor 328. FIG. 3 further includes the resistors 112, 114 of FIG. 1.

The capacitor 302 of FIG. 3 includes a first terminal and a second terminal. The first terminal of the capacitor 302 is coupled to the alert pin 108 and the first current terminal of the transistor 326. The second terminal of the capacitor 302 is coupled to the first terminal of the switch 306. The capacitor 302, if the switch 306 is closed (e.g., creating a short circuit) during a first phase, stores a voltage corresponding to the voltage at the alert pin 108 which corresponds to the voltage at the second terminal of the resistor 112. if the switch 306 is open (e.g., creating an open circuit) during a second phase, the capacitor 302 holds the sampled voltage at the second plate of the capacitor 302 because the second plate of the capacitor 302 is coupled to the high impedance state at the first input terminal of the amplifier.

The capacitor 304 of FIG. 3 includes a first terminal and a second terminal. The first terminal of the capacitor 304 is coupled to the alert pin 110 and the first current terminal of the transistor 323. The second terminal of the capacitor 304 is coupled to the first terminal of the switch 308. The capacitor 304, if the switch 308 is closed (e.g., creating a short circuit) during a first phase, stores a voltage corresponding to the voltage at the alert pin 108 which corresponds to the voltage at the second terminal of the resistor 112. If the switch 306 is open (e.g., creating an open circuit) during a second phase, the capacitor 304 holds the sampled voltage at the second plate of the capacitor 304 because the second plate of the capacitor 304 is coupled to the high impedance state at the first input terminal of the amplifier.

The switch 306 of FIG. 3 is a switch that can be opened (e.g., disabled or operate as an open circuit) or closed (e.g., enabled or operate as a closed switch) based on a signal from the controller 106 of FIG. 1. The switch 306 includes a first terminal and a second terminal. The first terminal of the switch 306 is coupled to the second terminal of the capacitor 302. The second terminal of the switch 306 is coupled to the second terminal of the switch 308, the first terminal of the switch 310 and the first input terminal of the amplifier 314. In some examples, the switch 306 includes a third terminal coupled to the controller 106 of FIG. 1 to control whether the switch 306 is enabled/disabled. The controller 106 of FIG. 1 closes the switch 306 during the first phase and opens the switch 306 during the second phase. In some examples, the switch 306 is implemented by a transistor (e.g., a field effect transistor (FET)).

The switch 308 of FIG. 3 is a switch that can be opened (e.g., disabled or operate as an open circuit) or closed (e.g., enabled or operate as a closed switch) based on a signal from the controller 106 of FIG. 1. The switch 308 includes a first terminal and a second terminal. The first terminal of the switch 308 is coupled to the second terminal of the capacitor 304. The second terminal of the switch 308 is coupled to the second terminal of the switch 306, the first terminal of the switch 310 and the first input terminal of the amplifier 314. In some examples, the switch 308 includes a third terminal coupled to the controller 106 of FIG. 1 to control whether the switch 308 is enabled/disabled. The controller 106 of FIG. 1 closes the switch 308 during the first phase and opens the switch 308 during the second phase. In some examples, the switch 308 is implemented by a transistor (e.g., a field effect transistor (FET)).

The switch 310 of FIG. 3 is a switch that can be opened (e.g., disabled or operate as an open circuit) or closed (e.g., enabled or operate as a closed switch) based on a signal from the controller 106 of FIG. 1. The switch 310 includes a first terminal and a second terminal. The first terminal of the switch 310 is coupled to the second terminal of the switch 306, the second terminal of the switch 308, and the first input terminal of the amplifier 314. The second terminal of the switch 310 is coupled to the common terminal 111 and the second terminal of the voltage generator 312. In some examples, the switch 310 includes a third terminal coupled to the controller 106 of FIG. 1 to control whether the switch 310 is enabled/disabled. The controller 106 of FIG. 1 closes the switch 310 during the first phase and opens the switch 310 during the second phase. In some examples, the switch 310 is implemented by a transistor (e.g., a field effect transistor (FET)).

The voltage supply 312 of FIG. 3 generates a bias voltage. The voltage supply 312 includes a first terminal and a second terminal. The first terminal of the voltage supply 312 is coupled to the second input terminal of the amplifier 314. The second terminal of the voltage supply 312 is coupled to the common terminal 111 and the second terminal of the switch 310. The voltage supply 312 generates a voltage small enough to keep the voltage at the alert pin 108 from dropping below a threshold, but large enough so that the output of the amplifier 314 is above a threshold voltage large enough to control the transistor 326. For example, the reference voltage may generate a voltage of −200 millivolts (mV) at the second input terminal of the amplifier 314.

The amplifier 314 of FIG. 3 is a differential amplifier that amplifies a difference between the voltage at the first input terminal and the voltage at the second input terminal. The amplifier 314 includes a first input terminal, a second input terminal, and an output terminal. The first input terminal (e.g., a non-inverting input) of the amplifier 314 is coupled to the second terminal of the switch 306, the second terminal of the switch 308, and the first terminal of the switch 310. The second input terminal (e.g., an inverting input) of the amplifier 314 is coupled to the first terminal of the voltage supply 312. In the example of FIG. 3, the second input terminal is inverted so that the opposite of the input voltage is applied to the inverting input of the amplifier 314. For example, if the voltage at the first input terminal is X Volts and the voltage at the second input terminal is Y Volts, the amplifier 314 will output voltage is A(X−(−Y)), where A is the gain of the amplifier 314. The amplifier 314 outputs the amplified difference between the voltages at the two input terminals at the output terminal of the amplifier 314.

The switch 316 of FIG. 3 is a switch that can be opened (e.g., disabled or operate as an open circuit) or closed (e.g., enabled or operate as a closed switch) based on a signal from the controller 106 of FIG. 1. The switch 316 includes a first terminal and a second terminal. The first terminal of the switch 316 is coupled to the output terminal of the amplifier 314 and the first terminals of the switches 318, 320. The second terminal of the switch 316 is coupled to a common terminal (e.g., ground) 111. In some examples, the switch 316 includes a third terminal coupled to the controller 106 of FIG. 1 to control whether the switch 316 is enabled/disabled. The controller 106 of FIG. 1 closes the switch 316 during the first phase and opens the switch 316 during the second phase. In some examples, the switch 316 is implemented by a transistor (e.g., a field effect transistor (FET)).

The switch 318 of FIG. 3 is a switch that can be opened (e.g., disabled or operate as an open circuit) or closed (e.g., enabled or operate as a closed switch) based on a signal from the controller 106 of FIG. 1. The switch 318 includes a first terminal and a second terminal. The first terminal of the switch 318 is coupled to the output terminal of the amplifier 314 and the first terminals of the switches 316, 320. The second terminal of the switch 318 is coupled to the first terminal of the switch 324 and the control terminal of the transistor 326. In some examples, the switch 318 includes a third terminal coupled to the controller 106 of FIG. 1 to control whether the switch 318 is enabled/disabled. The controller 106 of FIG. 1 closes the switch 318 during the first phase and opens the switch 318 during the second phase. In some examples, the switch 318 is implemented by a transistor (e.g., a field effect transistor (FET)).

The switch 320 of FIG. 3 is a switch that can be opened (e.g., disabled or operate as an open circuit) or closed (e.g., enabled or operate as a closed switch) based on a signal from the controller 106 of FIG. 1. The switch 320 includes a first terminal and a second terminal. The first terminal of the switch 320 is coupled to the output terminal of the amplifier 314 and the first terminals of the switches 316, 318. The second terminal of the switch 320 is coupled to the control terminal of the transistor 323. In some examples, the switch 320 includes a third terminal coupled to the controller 106 of FIG. 1 to control whether the switch 320 is enabled/disabled. The controller 106 of FIG. 1 closes the switch 320 during the first phase and opens the switch 320 during the second phase. In some examples, the switch 320 is implemented by a transistor (e.g., a field effect transistor (FET)).

The switch 322 of FIG. 3 is a switch that can be opened (e.g., disabled or operate as an open circuit) or closed (e.g., enabled or operate as a closed switch) based on a signal from the controller 106 of FIG. 1. The switch 322 includes a first terminal and a second terminal. The first terminal of the switch 322 is coupled to the second terminal of the switch 320 and the control terminal of the transistor 323. The second terminal of the switch 322 is coupled to a common terminal (e.g., ground) 111. In some examples, the switch 322 includes a third terminal coupled to the controller 106 of FIG. 1 to control whether the switch 322 is enabled/disabled. The controller 106 of FIG. 1 closes the switch 322 during the first phase and opens the switch 322 during the second phase. In some examples, the switch 322 is implemented by a transistor (e.g., a field effect transistor (FET)).

The switch 324 of FIG. 3 is a switch that can be opened (e.g., disabled or operate as an open circuit) or closed (e.g., enabled or operate as a closed switch) based on a signal from the controller 106 of FIG. 1. The switch 324 includes a first terminal and a second terminal. The first terminal of the switch 324 is coupled to the second terminal of the switch 318 and the control terminal of the transistor 326. The second terminal of the switch 324 is coupled to a common terminal (e.g., ground) 111. In some examples, the switch 324 includes a third terminal coupled to the controller 106 of FIG. 1 to control whether the switch 324 is enabled/disabled. The controller 106 of FIG. 1 closes the switch 324 during the first phase and opens the switch 324 during the second phase. In some examples, the switch 324 is implemented by a transistor (e.g., a field effect transistor (FET)).

The transistor 326 of FIG. 2 can cause current to flow from a first current terminal of the transistor 326 to a second current terminal of the transistor 326. The transistor 326 includes a first current terminal (e.g., a drain terminal), a second current terminal (e.g., a source terminal), and a control terminal (e.g., a gate terminal). The first current terminal of the transistor 326 is coupled to the first terminal of the capacitor 302 and the alert pin 108. The second current terminal of the transistor 326 is coupled to the first terminal of the resistor 328, the second current terminal of the transistor 323, and the controller 106 of FIG. 1 (e.g., via an example output terminal 330). The transistor 326 of FIG. 2 is an N-channel metal oxide field effect transistor (NMOS transistor or N-channel MOSFET). However, the transistor 326 can be any type of transistor. The voltage at the control terminal of the transistor 326 determines how much current will flow from the first current terminal to the second current terminal. For example, if the voltage at the control terminal of the transistor 326 is grounded (e.g., 0V), the transistor 326 acts as an open switch to block current at the first current terminal from flowing to the second current terminal. If the voltage at the control terminal of the of the transistor 326 is above 0V, the transistor 326 causes current to flow from the first current terminal to the second current terminal, the amount of current being based on the voltage at the control terminal of the transistor 326.

The transistor 323 of FIG. 2 can cause current to flow from a first current terminal of the transistor 323 to a second current terminal of the transistor 323. The transistor 323 includes a first current terminal (e.g., a drain terminal), a second current terminal (e.g., a source terminal), and a control terminal (e.g., a gate terminal). The first current terminal of the transistor 323 is coupled to the first terminal of the capacitor 304 and the alert pin 110. The second current terminal of the transistor 323 is coupled to the first terminal of the resistor 328, the second current terminal of the transistor 326, and the controller 106 of FIG. 1 (e.g., via the output terminal 330). The transistor 323 of FIG. 2 is an N-channel metal oxide field effect transistor (NMOS transistor or N-channel MOSFET). However, the transistor 323 can be any type of transistor. The voltage at the control terminal of the transistor 323 determines how much current will flow from the first current terminal to the second current terminal. For example, if the voltage at the control terminal of the transistor 323 is grounded (e.g., 0V), the transistor 323 acts as an open switch to block current at the first current terminal from flowing to the second current terminal. If the voltage at the control terminal of the of the transistor 323 is above 0V, the transistor 323 causes current to flow from the first current terminal to the second current terminal, the amount of current being based on the voltage at the control terminal of the transistor 323.

The resistor 328 of FIG. 2 is an output resistor. The resistor 328 includes a first terminal and a second terminal. The first terminal of the resistor 328 is coupled to the second current terminal of the transistor 326, the second current terminal of the transistor 323, and the controller 106 of FIG. 1 via the output terminal 330. The second terminal of the resistor 328 is coupled to the common terminal 111. The output resistor 328 generates a path to ground for the current from the second current terminal of the transistor 326 to flow toward, thereby generating a voltage at the first terminal of the resistor 328. The voltage at the first terminal of the resistor 328 corresponds to the resistance of the resistor 112 of FIG. 1. The voltage is transmitted to the controller 106 of FIG. 1 via the output terminal 330 to determine the resistance of the resistor 112.

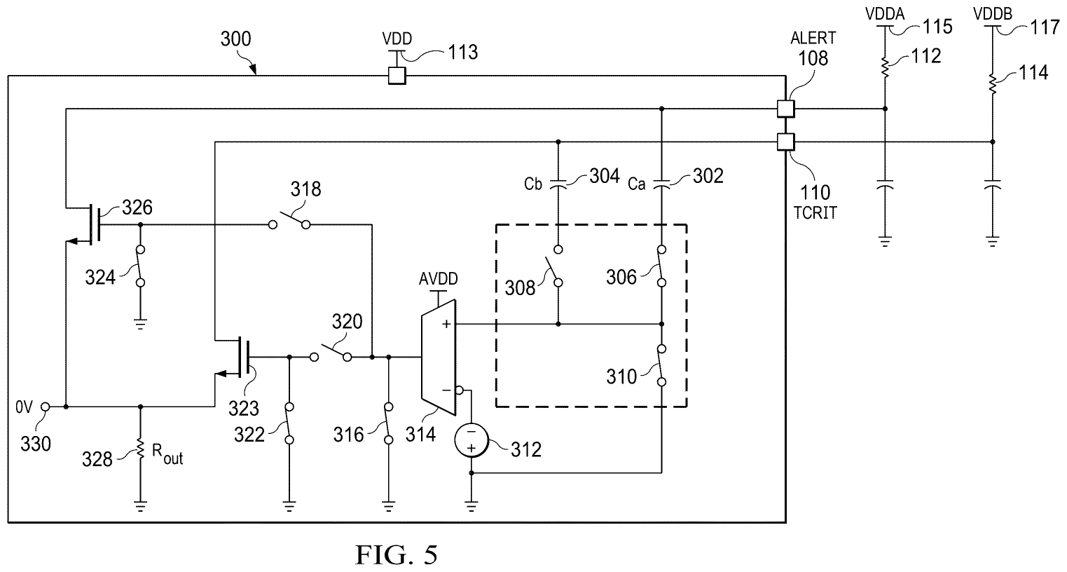

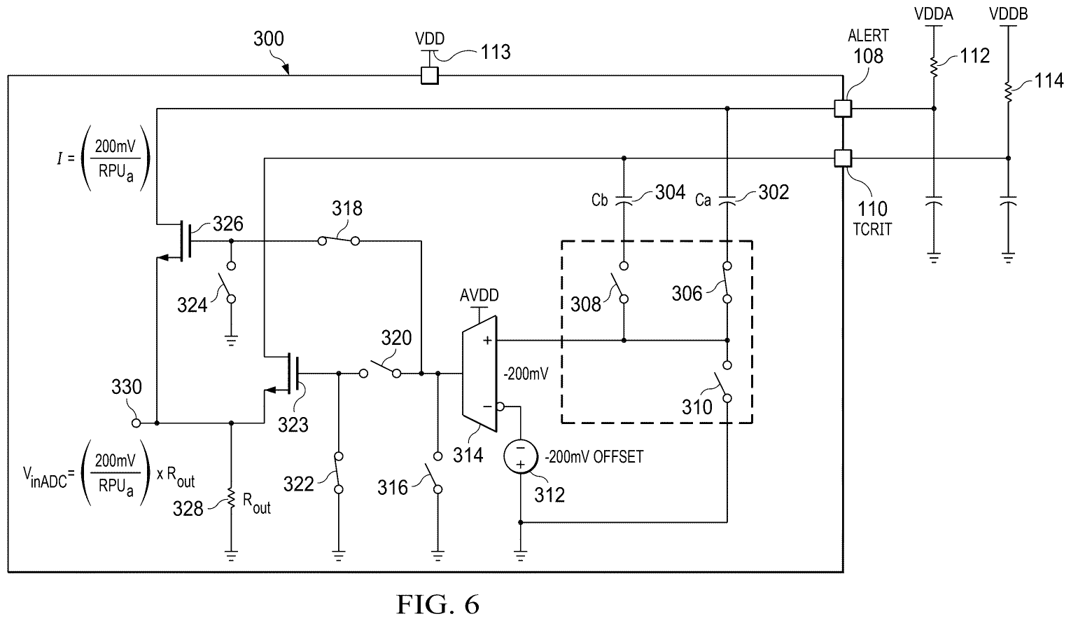

The operation of the circuitry 300 of FIG. 3 is based on the control of the switches 306, 308, 310, 316, 320, 322, 324. For example, to determine the resistance of the resistor 112, the controller 106 of FIG. 1 closes the switches 306, 310, 316, 322, 324 and opens switches 308, 318, 320 during a first phase to charge the capacitor 302. During a second phase the controller 106 opens the switches 308, 310, 316, 320, 322, 324 and closes switches 306, 318 to generate a voltage across the resistor 328 that corresponds to the resistance of the resistor 112, similar to the description of the circuitry 200 of FIG. 2. To determine the resistance of the resistor 112, the controller 106 of FIG. 1 closes the switches 308, 310, 316, 322, 324 and opens switches 306, 318, 320 during a first phase to charge the capacitor 302. During a second phase the controller 106 opens the switches 306, 308, 310, 316, 322, 324 and closes switch 308, 320 to generate a voltage across the resistor 328 that corresponds to the resistance of the resistor 112, similar to the description of the circuitry 200 of FIG. 2. An example operation is further described below in conjunction with FIGS. 5 and 6.

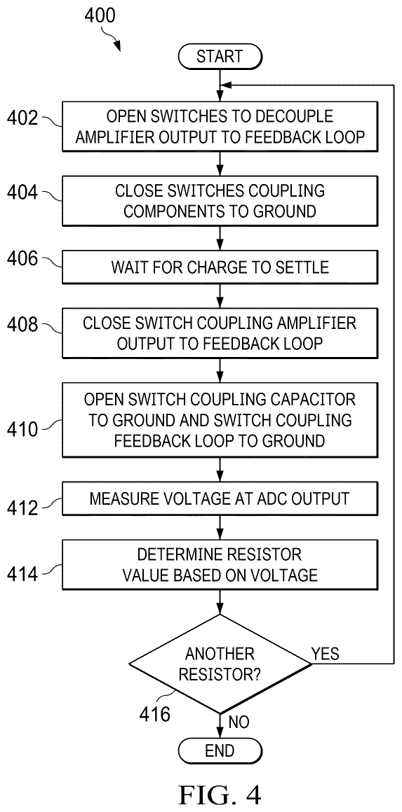

FIG. 4 is a flowchart representative of example machine readable instructions or example operations 400 that may be executed, instantiated, or performed by programmable circuitry to determine the resistance of a pull-up resistor (e.g., on or more of the resistor 112 or the resistor 114 of FIG. 1). The example machine readable instructions or example operations 400 may be implemented by the controller 106 of FIG. 1. The example machine-readable instructions or the example operations 400 of FIG. 4 begin at block 402, at which the controller 106 opens the switches 318, 320 to decouple the output of the amplifier 314 output from the feedback loop. For example, the controller 106 transmits one or more signals (e.g., voltages) to open the switches 318, 320. Also, the controller 106 closes the switches 316, 322, 324 to couple the control terminals of the transistors 323, 326 to ground.

At block 404, the controller 106 closes the switches 306, 310 to couple the capacitor 302 to ground. As described above, coupling the capacitor 302 to ground allows the capacitor 302 to charge to the supply voltage coupled to the first terminal of the resistor 112. At block 406, the controller 106 waits for a duration of time for the charge to settle (e.g., for the capacitor 302 to charge to the supply voltage). At block 408, the controller 106 closes the switches 318 to couple the output of the amplifier 314 to a feedback loop. At block 410, the controller 106 opens the switch 310 and opens the switches 316, 322, 324 to remove the connection of the control terminals of the transistors 323, 326 from the connection to ground. As described above, the amplifier 314 causes the voltage at the inputs to settle to the same input voltage and because the voltage source 312 outputs a −200 mV, for example, to the second input terminal of the amplifier 314, the voltage at the at the second terminal of the capacitor 302 will be −200 mV. Thus, the current through the resistor 328 will generate an output voltage that corresponds to the resistance of the resistor 112. The voltage is sampled by an ADC to generate a digital value that corresponds to the resistance of the resistor 112.

At block 412, the controller 106 measures the voltage (e.g., digital value) at the output of the ADC. At block 414, the controller 106 determines the resistance of the resistor 112 based on the digital voltage value output by the ADC. The controller 106 can store the determined resistance of the resistor 112 in memory or storage. At block 416, the controller 106 determines if there is another pull-up resistor that is coupled to the sensor 102 via an additional input. If the controller 106 determines that there is another resistor to process (block 416: YES), control returns to block 402. If the controller 106 determines that there is not another resistor to process (block 416: NO), the process ends.

FIG. 5 illustrates the example circuitry 300 of FIG. 3 when the controller 106 controls the switches for the first phase when determining the resistance of the resistor 112. FIG. 5 includes the pins 108, 110 and the resistors 112, 114 of FIGS. 1 and 3. FIG. 5 further includes the capacitors 304, 302, the switches 306, 308, 310, 316, 318, 320, 322, 324 to selectively couple one terminal of the respective switch to a second terminal of the respective switch, the example amplifier 314, the example transistors 323, 326, and the example resistor 328 of FIG. 3.

In the example of FIG. 5, the controller 106 outputs a signal to close the switches 306, 310, 316, 322, 324 to operate as short circuits. Also, the controller 106 outputs a signal to open the switches 308, 318, 320 to operate as open circuits. Because the switches 306, 310 are closed, the capacitor 302 is coupled from the VDDA supply voltage (e.g., via the resistor 112) to the common terminal 111 to charge the capacitor 302 to VDDA. Because the switch 308 is open, the capacitor 304 does not charge. Because the switch 316 is closed, the output of the amplifier 314 is grounded. Because the switches 318, 320 are open, the voltage at the output of the amplifier 314 does not control the transistors 323, 326. Also, because the switches 322, 324 are closed, the control terminal of the transistors 323, 326 are grounded, thereby disabling the transistors 323, 326 (e.g., so that current between the two current terminals is blocked). After the capacitor 302 has been charged for a duration of time (e.g., to store the VDDA charge), the controller 106 changes the control of the switches 306, 308, 310, 316, 318, 320, 322, 324 for a second phase to generate an output voltage that corresponds to the resistance of the resistor 112, as further described below in conjunction with FIG. 6.

FIG. 6 illustrates the example circuitry 300 of FIGS. 3 and 5 when the controller 106 controls the switches for the first second phase when determining the resistance of the resistor 112. FIG. 5 includes the pins 108, 110 and the resistors 112, 114 of FIGS. 1 and 3. FIG. 5 further includes the capacitors 304, 302, the switches 306, 308, 310, 316, 318, 320, 322, 324, the example amplifier 314, the example transistors 323, 326, and the example resistor 328 of FIGS. 3 and 5.

In the example of FIG. 6, the controller 106 outputs a signal to close the switches 306, 316, 318, 322 to operate as short circuits. Also, the controller 106 outputs a signal to open the switches 308, 310, 320, 324 to operate as open circuits. Because the switch 306 is closed and switch 310 is open, the second plate of the capacitor 302 is coupled to the high impedance first input terminal of the amplifier 314. Accordingly, the capacitor 302 will hold the VDDA voltage. Because the switch 318 is closed, the output voltage from the amplifier 314 controls the transistor 326 to make the voltage at the input terminals of the amplifier 314 equal. Because the voltage at the second input terminal corresponds to the offset voltage generated by the voltage supply 312 (e.g., −200 mV), the amplifier 314 controls the transistor 326 (e.g., cause the transistor 326 to operate as a closed switch) to conduct current until the voltage at the first input terminal is also −200 mV, thereby causing the voltage at the pin 108 to be VDDA-200 mV. Because the voltage at the pin 108 is VDDA-200 mV, the current from the resistor 112 and into the first current terminal of the transistor 326 is 200 mV/R112 (e.g., (VDDA-(VDDA-200 mV))/R112). Because the transistor 326 is enabled (e.g., operating as a closed switch), the 200 mV/R112 current will flow across the resistor 328 to generate an output voltage of (200 mV/R112)*Rout. As described above, the controller 106 includes an ADC to convert the analog voltage output ((200 mV/R112)*Rout) to a digital value that corresponds to the resistance of the resistor 112. The controller 106 can determine the resistance of the resistor 112 because the resistance of the resistor 328 is known. To determine the resistance of the resistor 114, a similar process to FIGS. 5 and 6 occurs. However, during the first phase and second phases, the switch 308 will be closed. Also, during the second phase switch 320 will be closed.

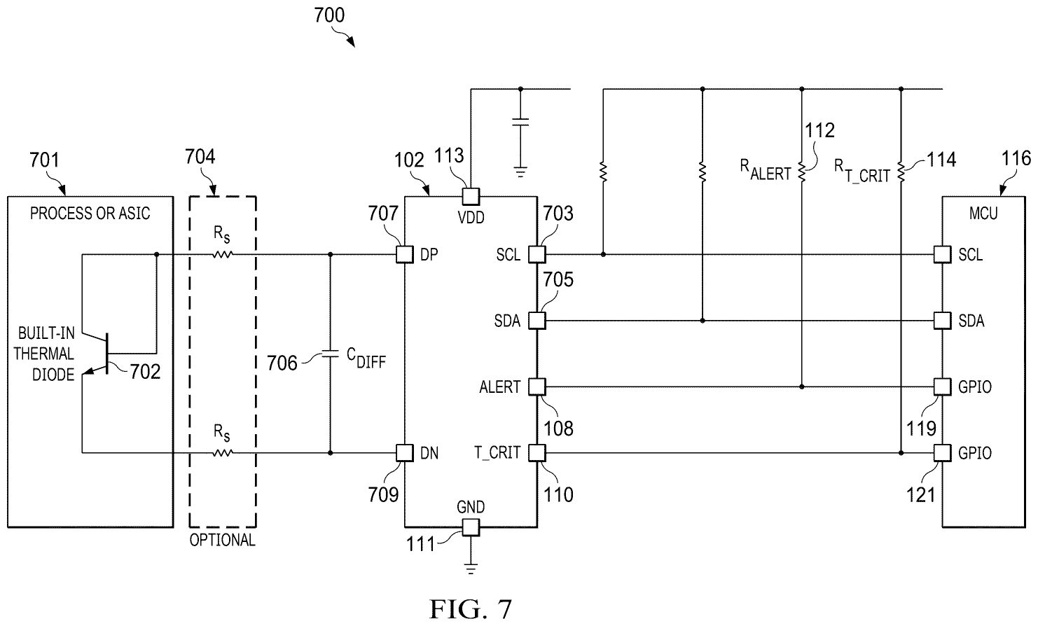

FIG. 7 is an example system 700 including the sensor 102 and device 116 of FIG. 1. The system 700 further includes the resistors 112, 114 of FIG. 1. The system 700 further includes an external sensing component 701, which includes a thermal diode 702, example resistors 704, and an example capacitor 706.

The sensor 102 includes eight pins or terminals. A first terminal (VDD) of the sensor 102 is coupled to a supply voltage. A second terminal (SCL) 703 of the sensor 102 is coupled to the device 116 and a pull-up resistor. A third terminal (SDA) 705 of the sensor 102 is coupled to the device 116 and a pull-up resistor. A fourth terminal (ALERT) of the sensor 102 corresponds to the pin 110 of FIG. 1. A fifth terminal of the (T_CRIT) of the sensor 102 corresponds to the pin 112 of FIG. 1. The sixth terminal (GND) of the sensor 102 is coupled to a common terminal 111. A seventh terminal (DP) 707 of the sensor 102 is coupled to the external sensing component 701 (e.g., via one of the optional resistors 704). An eight terminal (DN) 709 of the sensor 102 is coupled to the external sensing component 701 (e.g., via a second one of the optional resistors 704. The SCL terminal 703 of the sensor 102 is an input terminal that obtains an open-drawing serial clock from the device 116. The SDA terminal 705 is an input/output terminal that is dedicated to an open-drain serial data line.

The external sensing component 701 of FIG. 7 may be an external sensor, circuit, ASIC, etc. that can sense an environmental characteristic (e.g., temperature). The external sending component 701 includes the terminal diode 702 to generate a voltage between two terminals that corresponds to a sensed temperature. In this manner, the sensor 102 can determine the temperature sensed by the sensing component 701 based on the voltages at the DP terminal 707 and the DN terminal 709.

The resistors 704 and capacitor 706 of FIG. 7 are optional components that can be used to reduce error associated with the sensing component 701. The resistors 704 each include a first terminal and a second terminal. The respective first terminals of the resistors 704 are coupled to the sensing component 701. The respective second terminals of the resistors 704 are coupled to the corresponding terminals DP, DN 707, 709 of the sensor 102. The capacitor has a first terminal and a second terminal. The first terminal of the capacitor is coupled to the second terminal of the first resistor of the resistor 704 and the DP terminal 707 of the sensor 102. The second terminal of the capacitor is coupled to the second terminal of the second resistor of the resistor 704 and the DN terminal 709 of the sensor 102.

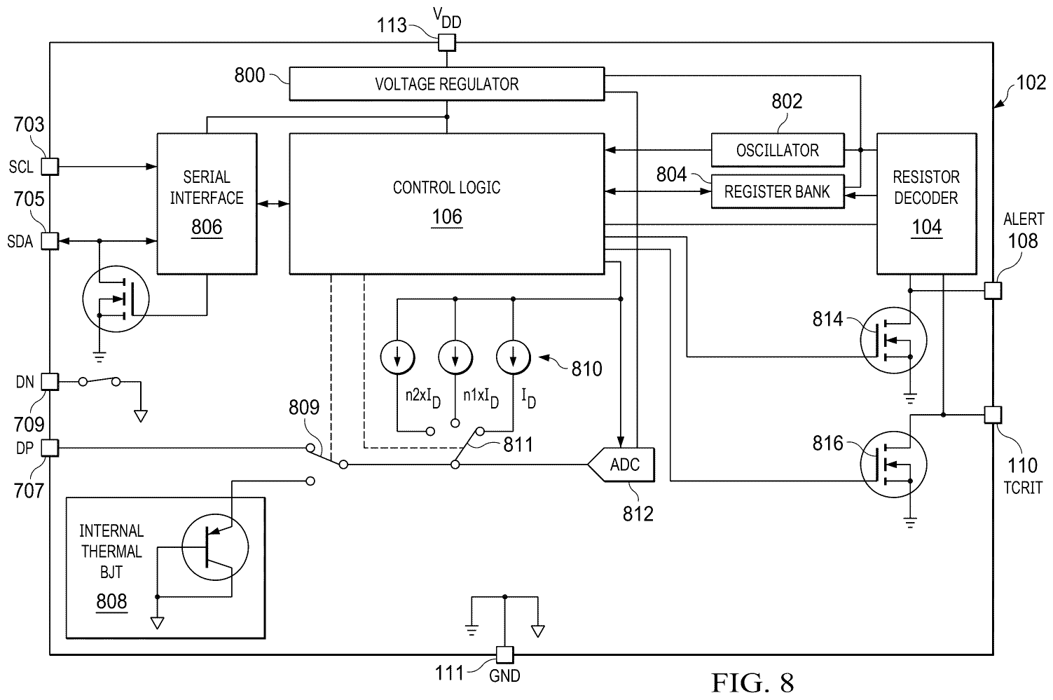

FIG. 8 is an example implementation of the sensor 102 of FIG. 1. The example sensor 102 of FIG. 8 includes the controller 106 (also referred to as control logic) and the resistor decoder 104 of FIG. 1. The sensor 102 of FIG. 8 further includes an example voltage regulator 800, an example oscillator 802, an example register bank 804, an example serial interface 806, an example thermal transistor 808, example switches 809, 811, example current sources 810, an example ADC 812, and example transistors 814, 816.

The controller 106 of FIG. 6 is coupled to the voltage regulator 800, the oscillator 802, the register bank 804, the serial interface 806, example switches 809, 811, the ADC 812, and the transistors 814, 816. The resistor decoder 104 is coupled to the oscillator 802, the register bank 804, the transistors 814, 816 and the pins 108, 110, and the controller 106. The voltage regulator 800 is coupled to a supply voltage terminal (VDD) the resistor decoder 104, the control logic 106, the oscillator 802, the register bank 804, the serial interface 806, and the ADC 812. The oscillator 802 is coupled to the voltage regulator 800 and the controller 106. The register bank 804 is coupled to the voltage regulator 800 and the control logic 106. The serial interface 806 is coupled to the SCL terminal 703 and SDA terminal 705, a transistor, the voltage regulator 800, and the control logic 106. The thermal transistor 808 is coupled to the switch 809. The switch 809 is coupled to the thermal transistor 808, the DP terminal 707, the control logic 106, and the switch 811. The current source circuitries 810 is coupled to the voltage regulator 800 and the switch 811. The switch 811 is coupled to the switch 809, the current source circuitries 810, and the ADC 812. The ADC 812 is coupled to the controller 106, the voltage regulator 800, and the switch 811. The transistor 814 includes a control terminal, a first current terminal, and a second current terminal. The control terminal of the transistor 814 is coupled to the controller 106. The first current terminal of the transistor 814 is coupled to the resistor decoder 104 and the alert pin 108. The second current terminal of the transistor 814 is coupled to the common terminal 111. The transistor 816 includes a control terminal, a first current terminal, and a second current terminal. The control terminal of the transistor 816 is coupled to the controller 106. The first current terminal of the transistor 816 is coupled to the resistor decoder 104 and the alert pin 110. The second current terminal of the transistor 816 is coupled to the common terminal 111.

The voltage regulator 800 of FIG. 8 regulates the supply voltage from the VDD terminal to an operating voltage of the components of the sensor 102. The voltage regulator 800 provides the regulated voltage to the connected components. The oscillator 802 generates a clock signal that is used by the controller 106 to execute instructions. The register bank 804 is memory that stores the voltage(s) output by the resistor decoder that corresponds to the resistance of the external pull-up resistors. The serial interface 806 receives data and clock signals from the device 116. Also, the serial interface 806 outputs data to the device 116.

The thermal transistor 808 of FIG. 8 is an internal temperature sensor that generates a voltage that corresponds to a sensed temperature. In some examples, the sensor 102 may be coupled to an external sensor (e.g., the sensing component 701 of FIG. 7). In such examples, the controller 106 can determine whether to use the data sensed by the external sensing component 701 or the internal sensing transistor 808 by controlling the switch 809. The current source circuitries 810 supply different amounts of currents to the ADC 812 based on the controllers 106 control of the switch 811. The current source circuitry 810 are used to measure a remote junction temperature. The current source circuitry 810 provide bias current for a remote diode or resistor. The ADC 812 converts the analog sensor data into digital data and passes the digital data to the controller 106. In this manner, the controller 106 can determine if the sensed data crosses a threshold that corresponds to the data stored in the register bank 804. If the sensed data does not cross the threshold (e.g., the temperature is above a threshold), the controller 106 applies a voltage to the control terminal of one or more of the transistors 814, 816 to conduct current creating a short to ground, thereby pulling the voltage at at least one of the first alert pin 108 or the second alert pin 110 to a low voltage. As described above, the device 116 is alerted to the temperature not crossing the threshold based on the voltage at the terminal coupled to at least one of the alert pins 108, 110 being a low voltage.

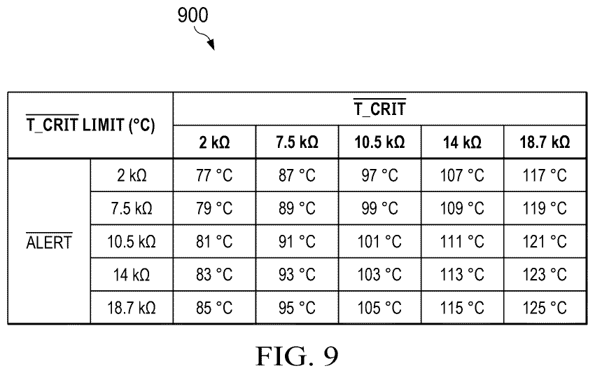

FIG. 9 illustrates an example table 900 of resistance values of the resistors 112, 114 that a user or manufacturer can select to achieve a temperature threshold (T_CRIT LIMIT) in Celsius. For example, if a user wants the sensor 102 to trigger a signal corresponding to an alert at the second alert pin 110 of FIG. 1 if the sensed temperature is at or above 99 degrees Celsius, the user will select the resistance of the first resistor 112 to be 7.5 kilo Ohms and the resistance of the second resistor 114 to be 10.5 kilo Ohms. Although the example table 900 includes various temperature thresholds corresponding to different resistance values. There may be more or less resistors and the resistance values or temperature threshold may be different based on different context.

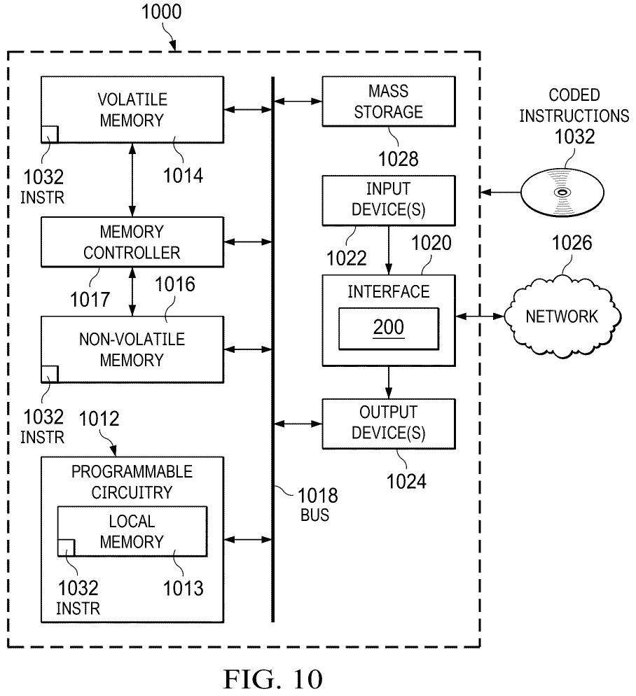

FIG. 10 is a block diagram of an example programmable circuitry platform 1000 structured to execute or instantiate the example machine-readable instructions or the example operations of FIG. 4 to implement the controller 106 of FIGS. 1 and 8. The programmable circuitry platform 1000 can be, for example, a server, a personal computer, a workstation, a self-learning machine (e.g., a neural network), a mobile device (e.g., a cell phone, a smart phone, a tablet such as an iPad™), or any other type of computing or electronic device.

The programmable circuitry platform 1000 of the illustrated example includes programmable circuitry 1012. The programmable circuitry 1012 of the illustrated example is hardware. For example, the programmable circuitry 1012 can be implemented by one or more integrated circuits, logic circuits, FPGAs, microprocessors, CPUs, GPUs, DSPs, or microcontrollers from any desired family or manufacturer. The programmable circuitry 1012 may be implemented by one or more semiconductor based (e.g., silicon based) devices. In this example, the programmable circuitry 1012 implements the controller 106 of FIGS. 1 and 8.

The programmable circuitry 1012 of the illustrated example includes a local memory 1013 (e.g., a cache, registers, etc.). The programmable circuitry 1012 of the illustrated example is in communication with main memory 1014, 1016, which includes a volatile memory 1014 and a non-volatile memory 1016, by a bus 1018. The volatile memory 1014 may be implemented by Synchronous Dynamic Random Access Memory (SDRAM), Dynamic Random Access Memory (DRAM), RAMBUS® Dynamic Random Access Memory (RDRAM®), or any other type of RAM device. The non-volatile memory 1016 may be implemented by flash memory or any other desired type of memory device. Access to the main memory 1014, 1016 of the illustrated example is controlled by a memory controller 1017. In some examples, the memory controller 1017 may be implemented by one or more integrated circuits, logic circuits, microcontrollers from any desired family or manufacturer, or any other type of circuitry to manage the flow of data going to and from the main memory 1014, 1016.

The programmable circuitry platform 1000 of the illustrated example also includes interface circuitry 1020. The interface circuitry 1020 may be implemented by hardware in any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 1022 are connected to the interface circuitry 1020. The input device(s) 1022 permit(s) a user (e.g., a human user, a machine user, etc.) to enter data or commands into the programmable circuitry 1012. The input device(s) 1022 can be implemented by, for example, an audio sensor, a microphone, a camera (still or video), a keyboard, a button, a mouse, a touchscreen, or a voice recognition system.

One or more output devices 1024 are also connected to the interface circuitry 1020 of the illustrated example. The output device(s) 1024 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, or speaker. The interface circuitry 1020 of the illustrated example, thus, may include a graphics driver card, a graphics driver chip, or graphics processor circuitry such as a GPU.

The interface circuitry 1020 of the illustrated example also includes a communication device such as a transmitter, a receiver, a transceiver, a modem, a residential gateway, a wireless access point, or a network interface to facilitate exchange of data with external machines (e.g., computing devices of any kind) by a network 1026. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1000 of the illustrated example also includes one or more mass storage discs or devices 1028 to store firmware, software, or data. Examples of such mass storage discs or devices 1028 include magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices or SSDs.

The machine-readable instructions 1032, which may be implemented by the machine-readable instructions of FIG. 4, may be stored in the mass storage device 1028, in the volatile memory 1014, in the non-volatile memory 1016, or on at least one non-transitory computer readable storage medium such as a CD or DVD which may be removable.

While an example manner of implementing the sensor 102 of FIG. 1 is illustrated in FIGS. 2, 3, and 5-8, one or more of the elements, processes, or devices illustrated in FIGS. 2, 3, and 5-8 may be combined, divided, re-arranged, omitted, eliminated, or implemented in any other way. Further, any one or more of the components of FIGS. 2, 3, and 5-8 may be implemented by hardware alone or by hardware in combination with software and firmware. Thus, for example, any one or more of the components of FIGS. 2, 3, and 5-8, could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example sensor 102 of FIGS. 2, 3, and 5-8 may include one or more elements, processes, or devices in addition to, or instead of, those illustrated in FIGS. 2, 3, and 5-8, or may include more than one of any or all of the illustrated elements, processes and devices.

Flowchart(s) representative of example machine-readable instructions, which may be executed by programmable circuitry to at least one of implement or instantiate the components of FIG. 4 or representative of example operations which may be performed by programmable circuitry to at least one of implement or instantiate the controller 106 of FIGS. 1 and 8. The machine-readable instructions may be one or more executable programs or portion(s) of one or more executable programs for execution by programmable circuitry such as the programmable circuitry 1012 shown in the example processor platform 1000 described below in connection with FIG. 10 and may be one or more function(s) or portion(s) of functions to be performed by the example programmable circuitry (e.g., an FPGA). In some examples, the machine-readable instructions cause an operation, a task, etc., to be carried out or performed in an automated manner in the real-world. As used herein, “automated” means without human involvement.

The program may be embodied in instructions (e.g., software or firmware) stored on one or more non-transitory computer readable or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIG. 4, many other methods of implementing the example controller 106 may alternatively be used. For example, the order of execution of the blocks of the flowchart(s) may be changed, or some of the blocks described may be changed, eliminated, or combined. Also, or alternatively, any or all of the blocks of the flow chart may be implemented by one or more hardware circuits (e.g., processor circuitry, discrete, integrated analog or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.). For example, the programmable circuitry may be one of or a combination of a CPU or an FPGA located in the same package (e.g., the same integrated circuit (IC) package or in two or more separate housings), one or more processors in a single machine, multiple processors distributed across multiple servers of a server rack, multiple processors distributed across one or more server racks, etc., or any combination(s) thereof.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, or executable by a computing device or other machine. For example, the machine-readable instructions may be stored in multiple parts, which are individually compressed, encrypted, or stored on separate computing devices, wherein the parts if decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C, Perl, Python, JavaScript, HyperText Markup Language (HTML), Structured Query Language (SQL), Swift, etc.

As mentioned above, the example operations of FIG. 4 may be implemented using executable instructions (e.g., computer readable or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, if the phrase “at least” is used as the transition term in, for example, a preamble of a claim, it is open-ended in the same manner as the term “comprising” and “including” are open ended. The term “or” if used, for example, in a form such as A, B, or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part if the first part is closer to the Earth than the second part. As noted above, a first part can be above or below a second part with one or more of: other parts therebetween, without other parts therebetween, with the first and second parts touching, or without the first and second parts being in direct contact with one another.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described examples, and other examples are possible, within the scope of the claims.

What is claimed is:

1. An integrated circuit comprising:
a capacitor having a first terminal and a second terminal;
a differential amplifier having a first input terminal, a second input terminal, and an output terminal, the first input terminal coupled to the second terminal of the capacitor, the second input terminal coupled to a voltage source;
a first switch having a first terminal and a second terminal, the first terminal of the first switch coupled to the first input terminal of the differential amplifier and the second terminal of the capacitor, the second terminal of the first switch coupled to the voltage source and a common terminal;
a resistor having a first terminal and a second terminal, the second terminal coupled to the common terminal; and
a second switch having a first terminal and a second terminal, the first terminal coupled to the output terminal of the differential amplifier, the second terminal coupled to the first terminal of the capacitor, the first terminal of the capacitor, and the first terminal of the resistor.

2. The integrated circuit of claim 1, wherein the first terminal of the capacitor is to be coupled to an external pull-up resistor.

3. The integrated circuit of claim 2, wherein a voltage at the first terminal of the resistor is equal to a voltage of the voltage source times a resistance of the resistor divided by the resistance of the external pull-up resistor.

4. The integrated circuit of claim 1, further including a controller coupled to the first terminal of the capacitor to control an output signal.

5. The integrated circuit of claim 4, wherein the controller is coupled to the first terminal of the resistor.

6. The integrated circuit of claim 5, wherein the controller is to determine a value for a pull-up resistor based on a voltage at the first terminal of the resistor, the pull-up resistor to be coupled to the first terminal of the capacitor.

7. The integrated circuit of claim 1, wherein the second terminal of the second switch is coupled to the first terminal of the capacitor and the terminal of the resistor via a transistor.

8. The integrated circuit of claim 7, wherein the transistor includes a first current terminal, a control terminal, and a second current terminal, the first current terminal coupled to the first terminal of the capacitor, the control terminal coupled to the output terminal of the differential amplifier, and the second current terminal coupled to the first terminal of the resistor.

9. A system comprising:
a first pull-up resistor;
a microcontroller having an input terminal coupled to the first pull-up resistor; and
an integrated circuit including:
a first input/output pin coupled to the first pull-up resistor and the input terminal of the microcontroller;
a capacitor having a first terminal and a second terminal, the first terminal coupled to the first input/output pin and a second terminal coupled to a differential amplifier;
the differential amplifier having a first input terminal, a second input terminal, and an output terminal, the first input terminal coupled to the second terminal of the capacitor, the second input terminal coupled to a voltage source;
a first switch having a first terminal and a second terminal, the first terminal of the first switch coupled to the first input terminal of the differential amplifier and the second terminal of the capacitor, the second terminal of the first switch coupled to the voltage source and a common terminal;
a resistor having a first terminal and a second terminal, the second terminal coupled to the common terminal; and
a second switch having a first terminal and a second terminal, the first terminal coupled to the output terminal of the differential amplifier, the second terminal coupled to the first input/output pin, the first terminal of the capacitor, and the first terminal of the resistor.

10. The system of claim 9, wherein the integrated circuit includes a controller including:
an input terminal coupled to the first terminal of the resistor; and
an output terminal coupled to the first input/output pin.

11. The system of claim 10, wherein the integrated circuit further includes a transistor coupled between the output terminal of the controller and the first input/output pin to selectively couple the first input/output pin to a common terminal.

12. The system of claim 10, wherein the controller is to close the first switch and open the second switch during a first phase of operation.

13. The system of claim 12, wherein the controller is to open the first switch and close the second switch during a second phase of operation.

14. The system of claim 13, wherein the controller is to obtain the voltage at the first terminal of the resistor during the second phase of operation.

15. The system of claim 9, further including a second pull-up resistor coupled to a second input/output pin of the integrated circuit, wherein the capacitor is a first capacitor, the integrated circuit further includes a third switch to selectively couple the first capacitor to the differential amplifier, the integrated circuit further includes a second capacitor coupled to the second input/output pin, and the integrated circuit further includes a fourth switch to selectively couple the second capacitor to the differential amplifier.

16. A system comprising:
a controller to output an indication to a first input pin based on a comparison of a temperature to a threshold;
a first pull-up resistor having a first terminal coupled to the first input pin and a second terminal coupled to a voltage supply; and
a resistor decoder to output a voltage having a voltage based on a resistance of the first pull-up resistor, wherein the controller is to determine the threshold based on the voltage.

17. The system of claim 16, wherein the controller is to cause the first input pin to be coupled to a common terminal if the temperature exceeds the threshold.

18. The system of claim 16, further including a second pull-up resistor having a first terminal coupled to a second input terminal, the second input terminal coupled to the resistor decoder.

19. The system of claim 16, further including a microcontroller coupled to the first input pin to receive an indication if the temperature exceeds the threshold.

20. The system of claim 16, wherein the controller is to store a lookup table that correlates a resistance of the first pull-up resistor with a temperature threshold.
